(19) United States
(12) Patent Application Publication
(10) Pub. No.: US 2011/0241746 A1
(43) Pub. Date: Oct. 6, 2011

(54) LOW POWER SMALL AREA STATIC PHASE INTERPOLATOR WITH GOOD LINEARITY

(75) Inventor: Chin-Ming Fu, Zhubei City (TW)

(73) Assignee: TAIWAN SEMICONDUCTOR MANUFACTURING CO., LTD., Hsin-Chu (TW)

(21) Appl. No.: 12/749,657

(22) Filed: Mar. 30, 2010

(51) Int. Cl. H03H 11/26

(52) U.S. Cl. 327/276

(57) ABSTRACT

A static phase interpolator includes first and second plurality of inverters coupled in parallel between an output node and first and second input nodes for receiving first and second clock signals, and first and second plurality of switch elements coupled to the first and second plurality of inverters for selectively turning on individual ones of the inverters in response to a phase control signal. An inverter is coupled the output node. The interpolator may include a slew rate controller coupled to the first and second input nodes. Also, each inverter of the interpolator may include a PMOS transistor in series with an NMOS transistor and have a respective one of the switch elements disposed between the PMOS and NMOS transistors.

### FIELD OF THE INVENTION

The present invention relates to phase interpolators and more particularly top static phase interpolators for use in clock and data recovery circuits.

### BACKGROUND OF THE INVENTION

Phase interpolators are used in clock and data recovery (CDR) circuits to generate clock signals with different phases and for picking the clock signal having the proper phase. Given two phase inputs (e.g., signals out of phase by 90°), the phase interpolator can provide an output having a phase between the two input phases.

FIG. 1 is a block diagram of a CDR circuit 10. The CDR circuit 10 includes a phase interpolator 15, which receives a pair of clock signals CLKP and CLKN of different phases. The output of the phase interpolator 15 is coupled to a sense amplifier flip flop (SAFF) or alternatively to a latch (together shown as SAFF/Latch 20), which receives as an input the data signal (INPUT DATA) to be recovered. One structure is a CMOS circuit and the other is a current mode logic (CML) circuit. A designer can choose either structure to perform the operation of obtaining data or edge information using a clock. Signals DATA and EDGE are outputted from the SAFF/Latch 20 to an optional demultiplexer 25, which provides the output signal DATA OUT for data processing by other digital modules. The data of signal INPUT DATA going into SAFF/Latch 20 is asynchronous. The data of signal DATA coming out of SAFF/Latch 20 is synchronized by the clock CLK from phase interpolator 15. The demultiplexed DATA and EDGE signals are provided to a finite state machine (FSM) acting as a digital filter 30, which outputs a Phase Code signal for control of the phase interpolator 15. The demultiplexer is optional and depends on the FSM operating speed.

The FSM block 30 of the CDR circuit 10 judges the present relationship between the clock edge (EDGE) and the signal DATA recovered by SAFF/Latch 20 using clock signal CLK. FIG. 2 illustrates possible relationships “late”, “aligned/perfect”, and “early” between the clock edge and the recovered data. The FSM 30 generates an appropriate phase code to reduce the phase difference between the clock CLK and the data. The phase interpolator 15 generates a corresponding phase of the clock signal based on the phase code for the SAFF/Latch 20 to use in generating the correct data.

One conventional architecture for the phase interpolator 15 is a current mode logic (CML) architecture. This architectures is adopted generally for its good linearity (i.e., equal spacing between generated interposed phases). However, the current mode logic architecture utilizes significant area and suffers from large power consumption.

An alternative to the current mode logic architectures is the so called static phase interpolator, an example of which is shown in FIG. 3. While the static phase interpolator of FIG. 3 is smaller in both size and power consumption compared to the CML based phase interpolator, the static phase interpolator does not provide good linearity. A phase interpolator with small footprint and power consumption while providing good linearity is desired.

### SUMMARY OF THE INVENTION

Embodiments are provided of a static phase interpolator for providing clock signals of different phases between a first phase of a first clock signal and a second phase of a second clock signal in response to a phase control signal. The static phase interpolator includes a first plurality of inverters coupled in parallel between a first input node for receiving the first clock signal and an output node, and a second plurality of inverters coupled in parallel between a second input node for receiving the second clock signal and the output node. A first plurality of switch elements is coupled to the first plurality of inverters for selectively turning on individual ones of the first plurality of inverters in response to the phase control signal, and a second plurality of switch elements is coupled to the second plurality of inverters for selectively turning on individual ones of the second plurality of inverters in response to the phase control signal. The interpolator has an inverter with an input coupled to the output node. In embodiments, the interpolator also includes a slew rate controller coupled to the first and second input nodes. In other embodiments, each inverter of the interpolator includes a PMOS transistor in series with an NMOS transistor and a respective one of the switch elements is disposed between the PMOS and NMOS transistors.

The above and other features of the present invention will be better understood from the following detailed description of the preferred embodiments of the invention that is provided in connection with the accompanying drawings.

### BRIEF DESCRIPTION OF THE DRAWINGS

The accompanying drawings illustrate preferred embodiments of the invention, as well as other information pertinent to the disclosure, in which:

FIG. 1 is a block diagram of a clock and data recovery (CDR) circuit with illustrative timing diagram.

FIG. 2 illustrates a timing diagram showing potential relationships between a clock signal and a data signal.

FIG. 3 illustrates a prior art static phase interpolator.

FIG. 4 illustrates an embodiment of a static phase interpolator according to various embodiments of the present invention.

FIG. 5 illustrates a switch unit within the static phase interpolator of FIG. 4.

FIG. 6 shows a timing diagram illustrating the general operation of a static phase interpolator such as is shown in FIGS. 3 and 4.

FIGS. 7A and 7B illustrate a conventional phase rotate order in a digital filter of a CDR circuit.

FIGS. 8A and 8B illustrate a phase rotate order in a digital filter of a CDR circuit according to an embodiment of the present invention.

### DETAILED DESCRIPTION

This description of the exemplary embodiments is intended to be read in connection with the accompanying drawings, which are to be considered part of the entire written description. Relative terms are for convenience of description and do not require that the apparatus be constructed or operated in a particular orientation. Terms concerning communication, coupling and the like, such as “connected” and “interconnected,” refer to a relationship wherein features communicate with one another either directly or indirectly through intervening structures, unless expressly described otherwise.

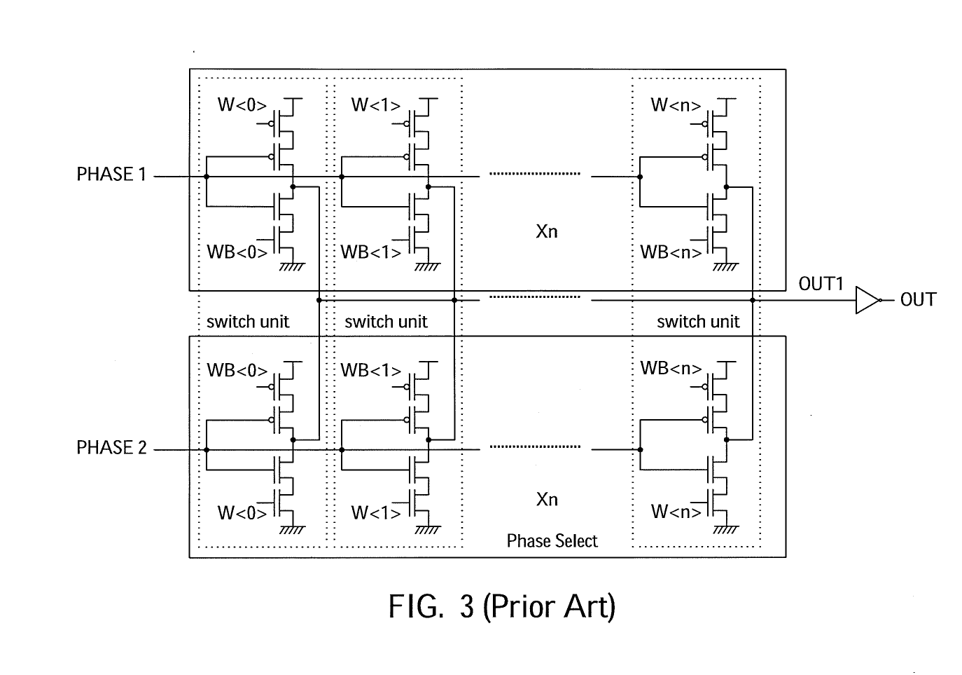

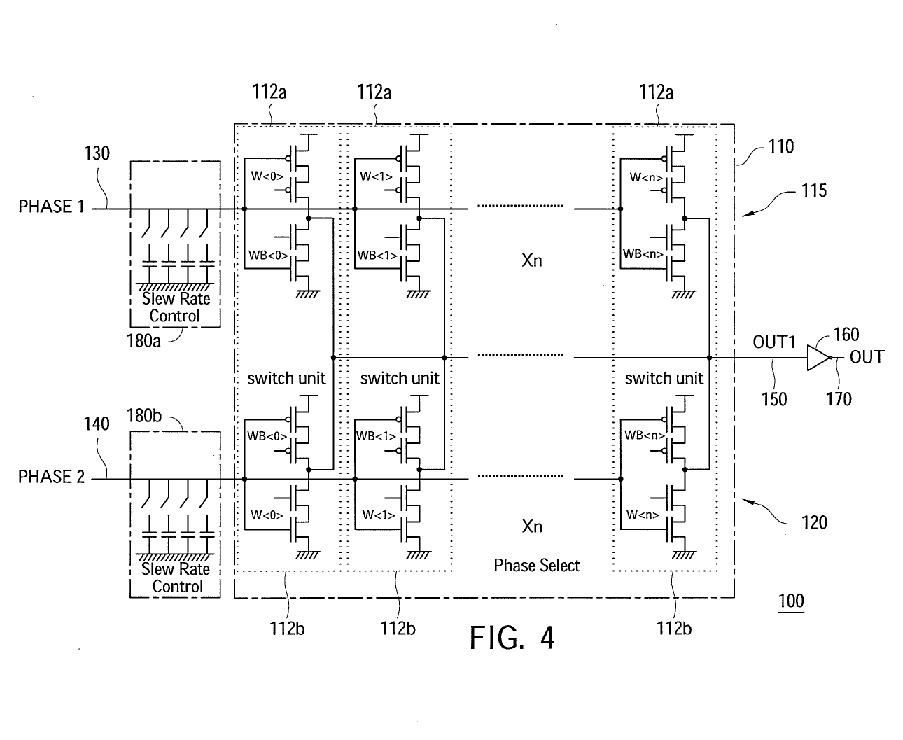

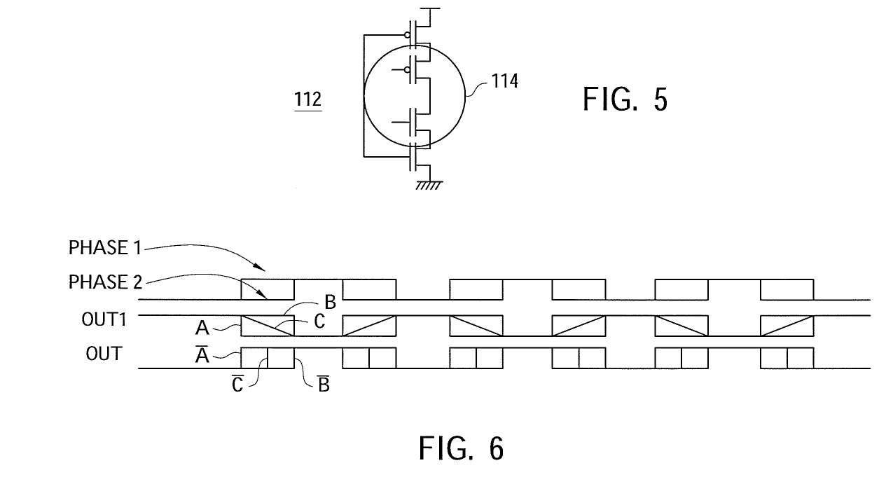

FIG. 4 is a circuit diagram of an exemplary embodiment of a static phase interpolator 100. FIG. 5 illustrates the configuration of one of the switch units within the static phase interpolator of FIG. 4. FIG. 6 is a timing diagram generally illustrating the operation of a static phase interpolator, such as is shown in FIGS. 3 and 4.

Referring first to FIG. 4, the static phase interpolator 100 has first and second input nodes 130, 140, respectively, for receiving first and second out-of-phase clock signals PHASE 1 and PHASE 2. These signals are preferably 90° out-of-phase though the phase difference between these signals can be anywhere from 0 to 180°. The static phase interpolator 100 includes a phase select circuit 110 with an upper path 115 of n number of phase select switch units 112 and a lower path 120 of n number of phase select switch units 112. Each phase select switch unit 112 (shown in FIG. 5 as well) includes an inverter formed from a upper PMOS transistor and a lower NMOS transistor coupled between respective supply nodes (e.g., VDD and VSS). The inverters of each path are coupled in parallel between either input node 130 or input node 140, to receive either PHASE 1 or PHASE 2 signal respectively, and an output node 150 (labeled with signal OUT1). Node 150 is coupled to output node 170 (labeled with signal OUT) through inverter 160. In embodiments, slew rate control is provided to the input nodes 130, 140 through first and second slew rate control circuits 180a, 180b.

Returning to the description of phase select switch units 112, each inverter of a phase select switch unit 112 has a switch element 114 connected to it for turning the inverter on/off responsive to a phase control signal. In the illustrated embodiment, the switch element 114 comprises a stacked pair of MOS transistors, such as a stacked pair of PMOS and NMOS transistors, connected between the PMOS and NMOS transistors that form the inverter of the phase select switch unit 112. The phase control signal is shown as consisting of a phase control code W<0> to W<n> and inverse phase control code WB<0> to WB<n>. The PMOS transistors of upper row 115 of phase select switch units 112 and the NMOS transistors of the lower path 120 are coupled to W<0> to W<n>, and the NMOS transistors of upper path 115 of phase select switch units 112 and the PMOS transistors of the lower row 120 are coupled to WB<0> to WB<n>. As such, individual ones of the inverters of the upper path 115 of switch units 112 are “on” when W<i> is a 0 and individual ones of the inverters of the lower path 120 of switch units 112 are “on” when W<i> is a 1.

The general operation of a static phase interpolator can be illustrated using the timing diagram of FIG. 6. As shown in FIG. 6, Phase 1 and Phase 2 signals are 90° out-of-phase. If all of W<0> to W<n> are 0, then all of the inverters in the upper path 115 are on and all of the inverters of the lower path 120 are off. The OUT1 waveform will be the inverse of the PHASE 1 signal, represented by signal A in the timing diagram. The OUT waveform is thus the inverse of signal A (i.e., the PHASE 1 signal).

If all W<0> to W<n> are 1, then all of the inverters in the upper path 115 are off and all of the inverters of the lower path 120 are on. The OUT1 waveform will be the inverse of the PHASE 2 signal, represented by signal B in the timing diagram. The OUT waveform is then inverse B (i.e., the PHASE 2 signal).

The slew rate of OUT1 is controlled according to the ratio of turned-on PMOS and NMOS transistors in the phase select circuit. By way of example, assume that W<0> to W<n-1> are each 0 and W<n> is 1. All of the inverters in the upper path 115 are on except for the nth inverter. All of the inverters of the lower path 120 are off except for the nth inverter. When the PHASE 1 signal changes from 0 to 1 and PHASE 2 is still 0, the OUT1 slew rate will be slower because there are 1 PMOS and n-1 NMOS transistors turned on at the same time.

Waveform C represents the OUT1 signal when half of the inverters in the upper path 115 and half of the inverters in the lower path 120 are on. The OUT waveform is inverse C. As shown in FIG. 6 inverse C has a phase half way between that of the PHASE 1 and PHASE 2 signals. If more of the upper path inverters are on, the phase of waveform inverse C will be closer to the phase of PHASE 1, and if more of the lower path inverters are on, the phase of inverse C will be closer to the phase of PHASE 2.

In summary, the phase control code W<0> to W<n> is used to adjust the slew rate of the OUT1 waveform. Different slew rates for waveform OUT1 result in different phases for waveform OUT. The maximum phase difference for OUT1 is |PHASE 1−PHASE 2|.

In the illustrated embodiment, the slew rate control circuits 180 can be used to control the input loading of the phase interpolator 100. In one embodiment, the slew rate control circuits 180 comprise a plurality of capacitors that can be selectively coupled through switches to the first and second input nodes 130, 140. If the switches of the slew rate control circuits 180 are all on, connecting the full complement of capacitors to the input nodes 130, 140, the loading is increased and the slew rate of the input waveform will be increased. The slope of the input waveform will influence the linearity of the phase interpolator 100. As such, the slew rate control mechanism can be used to improve the linearity of the phase interpolator 100 for different operating frequencies. The slew rate control can be inputted through control codes. The control circuits and operation are the same for both PHASE1 and PHASE2 slew rate control. The slew rate control is used, for example, when the clock speed is slower than desired or to account for outside environmental conditions, for example, process, supply voltage, and temperature variations. Slew rate control methods includes providing a different driving strength for the input or a different loading for input. FIG. 4 illustrates an example of slew rate control based on modifying the input loading.

In prior art static phase interpolators such as shown in FIG. 3, the switch transistors that are controlled by the phase code control signal are disposed between the two supply nodes above and below the inverters. These switch transistors are significantly larger than the NMOS and PMOS inverter transistors. Generally, for logical cascode circuits, the outside MOS devices size is twice that of the inside MOS devices size due to operating speed differences. This size difference adversely affects the linearity of the prior art phase interpolator. The prior art inverters operate as if there is a resistor in the middle of the inverter, which reduces linearity. As described above, slew rate control circuits 180 can be added to help improve the linearity of the static phase interpolator at different frequencies. In the alternative or in addition to the slew rate control circuit, as can be seen in FIGS. 4 and 5, the switch element 114 is disposed between the PMOS and NMOS transistors of the inverter of each switch unit 112. The P/NMOS transistors of the switch element 114 also have the same size as the P/NMOS transistors, respectively, that form the inverters. For phase interpolators, the key performance metric is linearity. Decreasing the size of the outside P/NMOS device sacrifices some operating speed but improves linearity. This embodiment provides not only for improved linearity in the interpolator performance but for significant reductions in the size of the static phase interpolator.

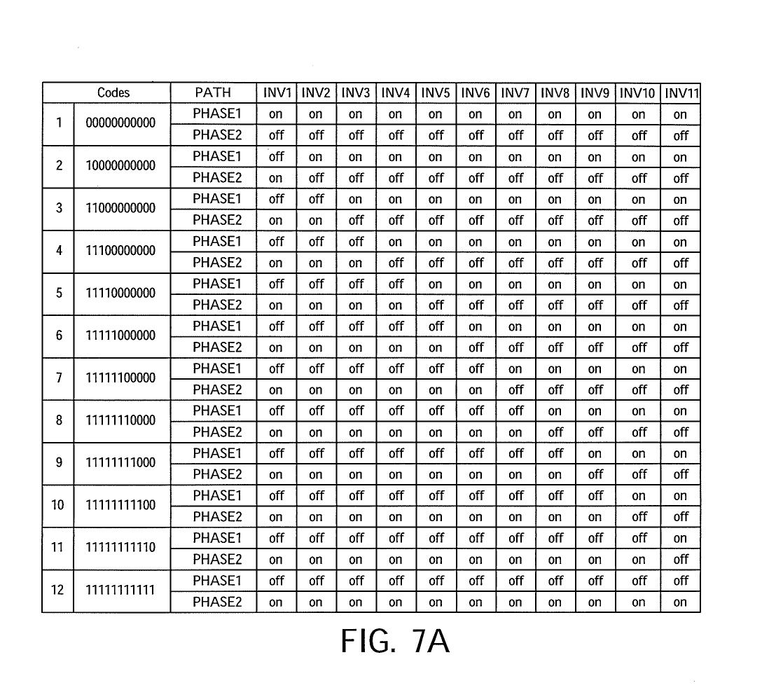

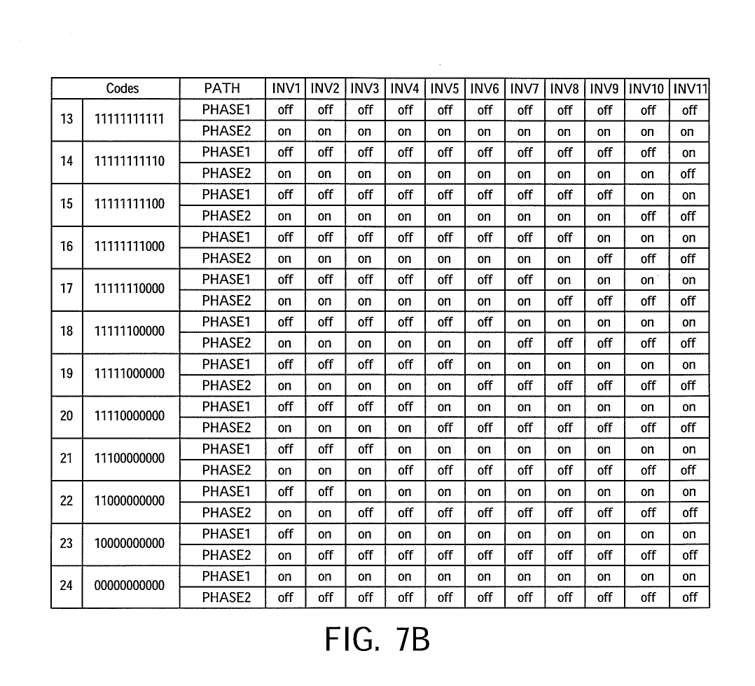

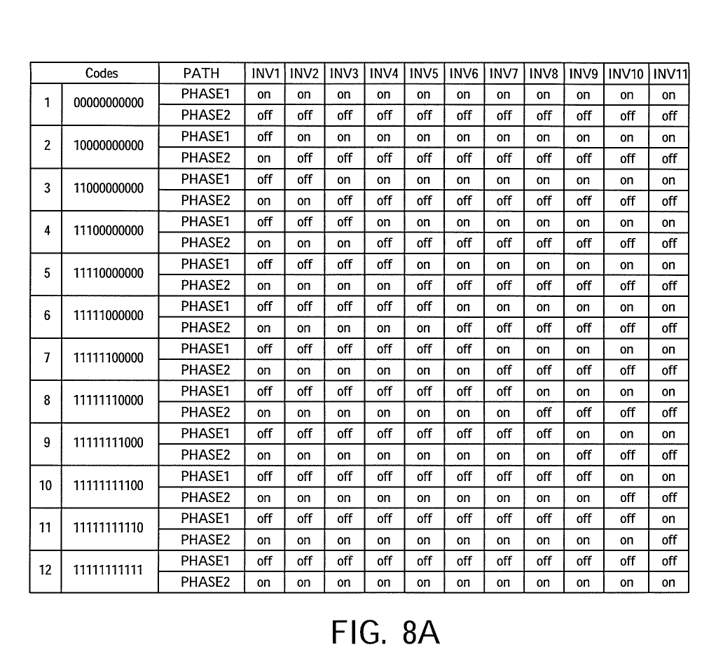

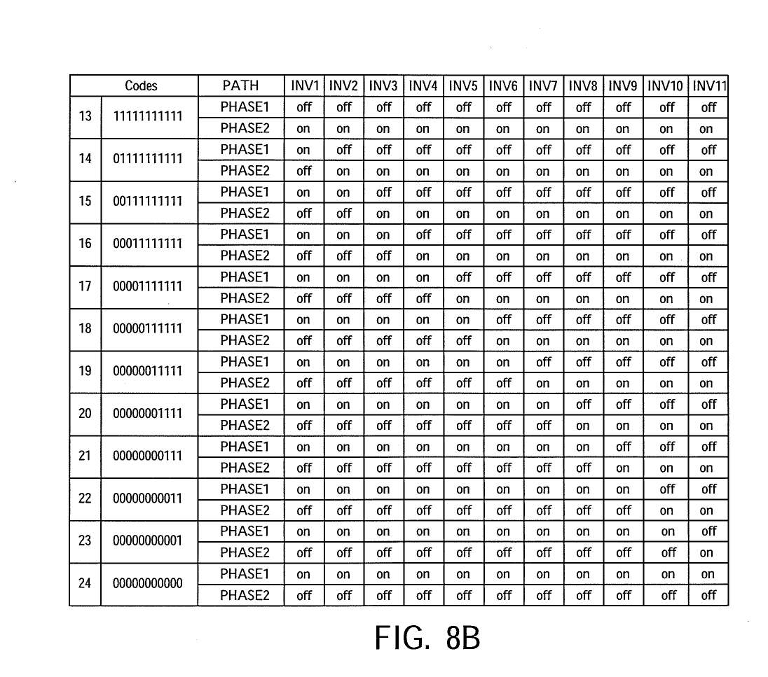

In embodiments of a CDR circuit, an improved phase rotate order can be implemented in the FSM (digital filter) of the CDR circuit 10 to improve linearity. For purposes of illustrating the improved phase rotate order, assume that the phase code is an eleven bit code and the upper and lower inverter paths of the phase interpolator each have eleven inverters and corresponding eleven switching elements for turning on/off the inverters in response to the phase code and inverse phase code. FIGS. 7A and 7B illustrate a conventional phase rotate order as implemented in a conventional FSM 30, and FIGS. 8A and 8B illustrate an embodiment of an improved phase rotate order. FIGS. 7A and 8A illustrate the upper part (rows 1 to 12) of the control codes for incrementing the phase of the clock signal outputted by the phase interpolator from 0° to 90°. These control codes are the same in both the conventional and proposed phase rotate orders. FIGS. 7B and 8B show the lower part (rows 14 to 23) for these rotate orders, i.e., for incrementing the phase of the clock signal outputted by the phase interpolator from 90° to 180°. As can be seen from these figures, rows 14 to 23 differ between FIGS. 7B and 8B.

The proposed order (FIGS. 8A and 8B) keeps the same triggering (i.e., turn on/off) order for the inverters when the phase rotates from the 1st code to the 12th code (0° to 90°) as from 13th code to 24th code (90° to 180°), whereas the conventional phase rotate order will cause the opposite turn on/off order when phase rotates from the 1st code to the 12th code (0° to 90°) compared to phase rotation from the 13th code to the 24th code (90° to 180°). For example, for the codes on rows 2 and 14, the codes for the conventional order are 10000000000 and 11111111110. The codes for the proposed phase rotate order are 10000000000 and 01111111111. For the conventional order, the turned-on inverters are the first inverter in the PHASE 2 inverter chain and inverters 2 to 11 in the PHASE 1 inverter chain for code 10000000000. But the turned-on inverters for code 11111111110 are the inverters 1 to 10 in the PHASE 2 inverter chain and the eleventh inverter in the PHASE 1 inverter chain.

As discussed above, different slew rates for the OUT1 waveform are used to generate different output phases. In order to improve the linearity of the transition between phases, the size of the inverters in the paths are not symmetrical for inverter[1] to inverter[11] in the PHASE 1 and PHASE 2 paths. That is, the sizes of inverter[1] to inverter[11] change from inverter[1] to inverter[11] (i.e., the size of inverter[1] is not equal to the size of inverter[2], and so on). As will be understood by those familiar with these devices, the sizes of inverters[1] to inverters[11], depends on the process nodes. Rules are established for the size relationships. For example, the inverter size can increase from inverter[1] to inverter[2] and then decrease from inverter[2] to inverter[6] and then increase from inverter[7] to inverter[11]. But the size of inverter[i] in the PHASE 1 path is equal to the size of inverter[i] in the PHASE 2 path. If the turn-on/off orders are not the same for code rows 1 to 12 and codes 13 to 24, the optimized size for each inverter will not be the same for these two conditions. Therefore, there is a conflict if the design seeks to optimize linearity for both codes 1 to 12 and for codes 13 to 24 when the turn-on/off orders are not the same. If the turn-on/off orders are the same for codes 1 to 12 and for 13 to 24, then the phase difference in the clock signal caused by the switching from the first code to the second code will be the same as the phase difference caused by the switch from the thirteenth code to the fourteenth code. And if the size of the inverters is optimized for codes 1 to 12, then the same optimized performance can be realized for codes 13 to 24. As such, for the proposed order, the turned-on inverters are the first inverter in the PHASE 2 inverter chain and the second to eleventh inverters in the PHASE 1 inverter chain for code 10000000000. And the turned-on inverters are the second to eleventh inverters in the PHASE 2 inverter chain and the first inverter in the PHASE 1 inverter chain for code 01111111111.

In summary, the triggering order (i.e., turning and inverter from “on” to “off” or “off” to “on” as the present state dictates) for the conventional phase rotate order is from inverter[1] to inverter [11] for codes 1 to 12 (0° to 90°) and from inverter[11] to inverter[1] for codes 13 to 24 (90° to 180°). But the triggering order for the proposed phase rotate order is from inverter[1] to inverter [11] for codes 1 to 12 (0° to 90°) and also from inverter[1] to inverter[11] for codes 13 to 24 (90° to 180°).

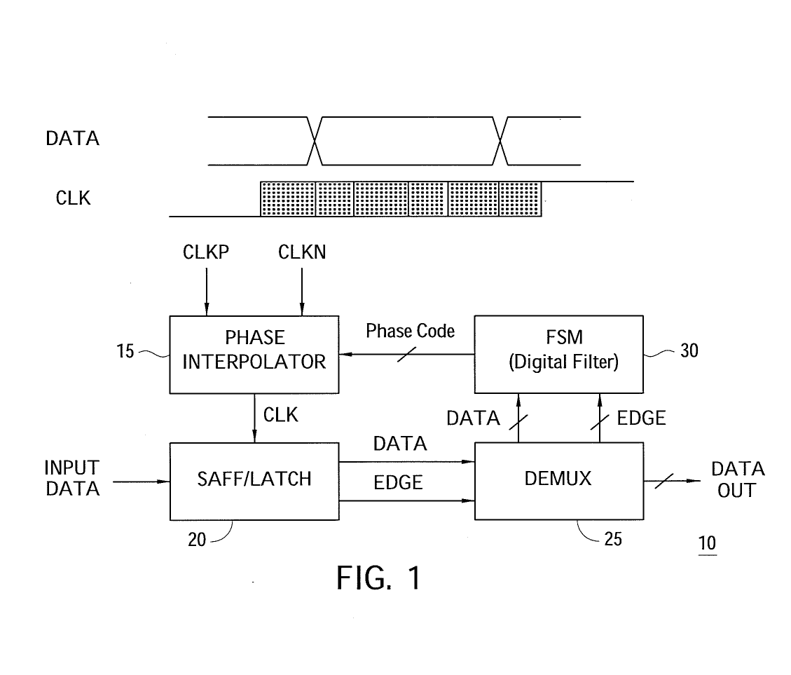

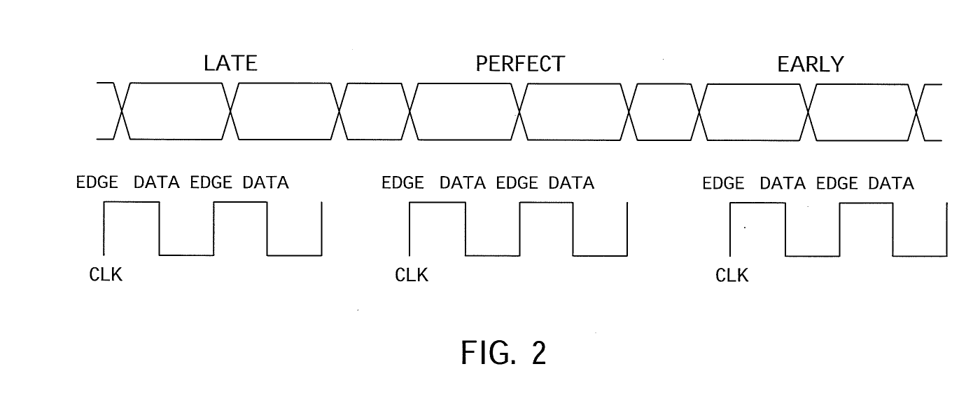

The specific phase rotate order can be implemented in the FSM (digital filter) 30 of FIG. 1. The phase rotate order causes the phase switch units 112 to be triggered in the same order from phases 90° to 180° as from 0° to 90°. Turning the switch units 112 on/off in the same order eases the difficulty in optimizing the linearity of the phase interpolator (i.e., helps to keep the same performance for the phase change from phase 1 to phase 2, etc. as from phase 1+90° to phase 2+90°.

The table below compares a conventional CML based phase interpolator, a conventional static phase interpolator and the proposed static phase interpolator, assuming the fabrication process is the TSMC 45 nm logic 0.9V (core device supply voltage) process. The area number for the conventional static phase interpolator assumes additional circuitry is implemented to help improve its linearity performance.

| | Conventional | Conventional | |
|---|---|---|---|
| | CML | Static Phase | Proposed Static |
| | Phase Interpolator | Interpolator | Phase Interpolator |
| Power Supply | 950 mV ± 50 mV | 950 mV ± 50 mV | 950 mV ± 50 mV |
| Temperature | −40~125° C. | −40~125° C. | −40~125° C. |
| Operating | 5 GHz & | 5 GHz & | 5 GHz & |
| Frequency | 2.5 GHz | 2.5 GHz | 2.5 GHz |
| | PCIE (PCI | PCIE Gen 1 & | PCIE Gen 1 & |
| | EXPRESS) | Gen 2 | Gen 2 |
| | Gen 1 & Gen 2 | | |
| Area | 8,150 μm² | 15,400 μm² | 3,500 μm² |
| Power | 25 mW | 8 mW | 7.5 mW |
| Consumption | | | |

As shown in the table, the area consumed by the proposed static phase interpolator is only 42% of that used by a CML based phase interpolator and only 23% of that used by a conventional static phase interpolator. The power consumption of the proposed static phase interpolator is only 30% of that used by a CML based phase interpolator and lower than that of a conventional static phase interpolator.

As those of ordinary skill in this art will understand, for different phase codes the phase interpolator will generate a different phase of the clock. There will be a phase step between two neighboring phase codes, such as between phase codes 1 and 2 in FIG. 7A. If there are a total of 12 phase codes, there will be 11 phase steps. Among these 11 phase steps, the maximum phase step/minimum phase step provides the index of linearity. Computer simulations, using optimized slew rate codes to provide appropriate slew rate for linearity, showed that the PI linearity (maximum step/minimum step) at both 5 GHz and 2.5 GHz is improved over conventional static phase interpolators and almost the same as conventional CML based phase interpolators. These results are shown in the tables below for the following design assumptions: typical case (TC); worst case (WC); best case (BC); high leakage current (HL); high Vt (HVT); slow/fast corner (SF); and fast/slow corner (FS).

PI Linearity (max. step/min. step) @ 5 GHz:

| Corner | TC | WC | BC | HL | HVT | SF | FS |
|---|---|---|---|---|---|---|---|
| Conventional CML | 1.47 | 1.55 | 1.66 | 1.98 | 1.49 | 1.51 | 1.51 |
| Conventional Static | 2.71 | 2.75 | 2.94 | 2.53 | 3.28 | 2.69 | 2.64 |
| Proposed Static | 1.45 | 1.71 | 1.97 | 1.90 | 1.96 | 1.44 | 1.96 |

PI Linearity (max. step/min. step) @ 2.5 GHz:

| Corner | TC | WC | BC | HL | HVT | SF | FS |
|---|---|---|---|---|---|---|---|
| Conventional CML | 1.8 | 1.76 | 1.78 | 1.56 | 1.93 | 1.81 | 1.91 |
| Conventional Static | 2.83 | 2.17 | 4.36 | 3.34 | 2.8 | 2.08 | 2.11 |
| Proposed Static | 1.24 | 1.41 | 1.18 | 1.59 | 1.82 | 1.40 | 1.40 |

As described above, an inverter architecture based static phase interpolator is provide having small area and low power consumption compared with CML based phase interpolators with improved linearity when compared to conventional static phase interpolators. A slew rate control mechanism can be implemented to help the phase interpolator improve linearity for different operating frequencies. Placing the PMOS/NMOS switch elements inside of the inverter helps to improve the linearity and decrease the size when compared with conventional static phase interpolators with switch elements disposed on the outside of the inverters. A phase rotate order is proposed that can be implemented in the FSM (digital filter) of a CDR circuit that helps to optimize the design for linearity more easily.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention.

1. A static phase interpolator for providing clock signals of different phases between a first phase of a first clock signal and a second phase of a second clock signal in response to a phase control signal comprising:
a first plurality of inverters coupled in parallel between a first input node for receiving the first clock signal and an output node;
a second plurality of inverters coupled in parallel between a second input node for receiving the second clock signal and the output node;
a first plurality of switch elements coupled to the first plurality of inverters for selectively turning on individual ones of the first plurality of inverters in response to the phase control signal;
a second plurality of switch elements coupled to the second plurality of inverters for selectively turning on individual ones of the second plurality of inverters in response to the phase control signal;
an inverter having an input coupled to the output node; and
a slew rate controller coupled to the first and second input nodes.

2. The static phase interpolator of claim 1, wherein the slew rate controller is operable to adjust input loading at the first and second input nodes to adjust a slew rate of the first and second clock signals.

3. The static phase interpolator of claim 2, wherein the slew rate controller includes a plurality of capacitors switchably coupled to the input nodes.

4. The static phase interpolator of claim 1, wherein each inverter comprises a PMOS transistor in series with an NMOS transistor, and a respective one of the switch elements is disposed between the PMOS and NMOS transistors of each inverter.

5. The static phase interpolator of claim 4, wherein each switch element comprises a pair of stacked PMOS and NMOS transistors.

6. The static phase interpolator of claim 5, wherein the PMOS and NMOS switch transistors have substantially the same size as the PMOS and NMOS inverter transistors, respectively, to which they are coupled.

7. The static phase interpolator of claim 5, wherein the phase control signal includes a phase control code and an inverse phase control code, wherein the PMOS transistors of the first switch elements and the NMOS transistors of the second switch elements are under control of the phase control code and the NMOS transistors of the first switch elements and the PMOS transistors of the second switch elements are under control of the inverse phase control code.

8. The static phase interpolator of claim 1, wherein the first and second phases are 90° apart.

9. A static phase interpolator for providing clock signals of different phases between a first phase of a first clock signal and a second phase of a second clock signal in response to a phase control signal comprising:
a first plurality of inverters coupled in parallel between a first input node for receiving the first clock signal and an output node;
a second plurality of inverters coupled in parallel between a second input node for receiving the second clock signal and the output node;
a first plurality of switch elements coupled to the first plurality of inverters for selectively turning on individual ones of the first plurality of inverters in response to the phase control signal; and
a second plurality of switch elements coupled to the second plurality of inverters for selectively turning on individual ones of the second plurality of inverters in response to the phase control signal; and
an inverter having an input coupled to the output node,
wherein each inverter comprises a PMOS transistor in series with an NMOS transistor, and a respective one of the switch elements is disposed between the PMOS and NMOS transistors of each inverter.

10. The static phase interpolator of claim 9, wherein each switch element comprises a pair of stacked PMOS and NMOS transistors.

11. (canceled)

11. (canceled)

12. The static phase interpolator of claim 10, wherein the first and second phases are 90° apart.

13. The static phase interpolator of claim 10, further comprising a slew rate controller coupled to the first and second input nodes operable to adjust input loading at the first and second input nodes to adjust a slew rate of the first and second clock signals.

14. The static phase interpolator of claim 10, wherein the slew rate controller includes a plurality of capacitors switchably coupled to the input nodes.

15. A clock and data recovery circuit comprising:
a data recovery module having inputs for receiving a data signal and a clock signal and outputs for outputting recovered data and clock edge signals;
a digital filter responsive to the recovered data and clock edge signals and providing an output phase code; and
a static phase interpolator for providing the clock signal in response to the output phase code,
wherein the static phase interpolator includes a plurality phase select switch units, and
wherein the output phase code triggers the phase select switch units to increment a phase of the clock signal in a phase rotate order, wherein the phase select switches are triggered in a selected order to increment the phase of the clock signal between 0° to 90°, wherein the phase select switch units are also triggered in the selected order to increment the phase of the clock signal between 90° to 180°.

16. The clock and data recovery circuit of claim 15, wherein the data recovery module comprises a sense amplifier flip flop or latch.

17. The clock and data recovery circuit of claim 15, wherein the phase select switch units of the static phase interpolator include:
a first plurality of inverters coupled in parallel between a first input node for receiving a first clock signal having a first phase and an output node;
a second plurality of inverters coupled in parallel between a second input node for receiving a second clock signal having a second phase and the output node;
a first plurality of switch elements coupled to the first plurality of inverters for selectively turning on individual ones of the first plurality of inverters in response to the phase code; and
a second plurality of switch elements coupled to the second plurality of inverters for selectively turning on individual ones of the second plurality of inverters in response to the phase code,
wherein the static phase interpolator further comprises an inverter having an input coupled to the output node.

18. The clock and data recovery circuit of claim 17,
wherein each inverter comprises a PMOS transistor in series with an NMOS transistor, and a respective one of the switch elements is disposed between the PMOS and NMOS transistors of each inverter, and
wherein the PMOS and NMOS switch transistors have substantially the same size as the PMOS and NMOS inverter transistors, respectively, to which they are coupled.

19. The clock and data recovery circuit of claim 17, wherein the static phase interpolator further comprises a slew rate controller coupled to the first and second input nodes.

20. The clock and data recovery circuit of claim 17, wherein the first and second phases are 90° apart.

21. The static phase interpolator of claim 10, wherein the phase control signal includes a phase control code and an inverse phase control code, wherein the PMOS transistors of the first switch elements and the NMOS transistors of the second switch elements are under control of the phase control code and the NMOS transistors of the first switch elements and the PMOS transistors of the second switch elements are under control of the inverse phase control code.

22. The static phase interpolator of claim 10, wherein the PMOS and NMOS switch transistors have substantially the same size as the PMOS and NMOS inverter transistors, respectively, to which they are coupled.
